(19) United States
(12) Patent Application Publication
(10) Pub. No.: US 2006/0160346 A1
(43) Pub. Date: Jul. 20, 2006

(54) Substrate bump formation

(75) Inventor: Yuji Hori, Ibaraki (JP)

Correspondence Address: VENABLE LLP, P.O. BOX 34385, WASHINGTON, DC, 20045-9998, US

(73) Assignee: Intel Corporation, Santa Clara, CA (US)

(21) Appl. No.: 11/037,138

(22) Filed: Jan. 19, 2005

(51) Int. Cl. H01L 21/44

(52) U.S. Cl. 438/612

(57) ABSTRACT

A layer of metal may be formed under a layer of solder in forming solder bumps. The metal may reduce the amount of solder necessary and may result in a corresponding reduction in solder defects.

### BACKGROUND OF THE INVENTION

When using known solder bump formation techniques, voids may form in the solder bumps during formation and reflow. The number of voids in the solder bumps may vary greatly among the different solder bumps on the package substrate. The presence of the voids can have a detrimental effect on the performance of the integrated circuit device. The voids may cause a failure at a maximum current through the semiconductor device. Additionally, current processes used to form solder bumps may result in the failure to form a solder bump at a point where a solder bump should have been be formed and an open failure due to low volume solder bumps, or a short failure due to large volume solder bumps.

There have been great advances in the optimization of solder print printing conditions and solder reflow profiles for reducing solder bump voids, missing bumps and low and large volume solder bumps. However, there are no robust processes currently available to eliminate solder bump voids, missing solder bumps, and low/large volume solder bumps.

### BRIEF DESCRIPTION OF THE DRAWINGS

The invention may be understood by referring to the following description and accompanying drawings, wherein like reference numbers generally indicate identical, functionally similar, and/or structurally similar elements.

FIGS. 1A-1C are cross sections of a semiconductor device package;

FIGS. 2A and 2B are schematic illustrations of a cross-sectional view of an integrated circuit device showing the processing step of forming a via;

FIG. 3 is a schematic illustration of a cross-sectional view of an integrated circuit device showing the processing step of forming a solder bump;

FIG. 4 is a schematic illustration of a cross-sectional view of an integrated circuit device showing the processing step of removing the mask layers;

FIG. 5 is a schematic illustration of a cross-sectional view of an integrated circuit device after the processing step of reflowing the solder bump;

FIG. 6 is a schematic illustration of a cross-sectional view of an integrated circuit device showing the processing step of flattening the solder bump;

FIG. 7 is a schematic illustration of a cross-sectional view of an integrated circuit device showing the processing step of forming a solder resist layer according to an embodiment of the invention;

FIG. 8 is a schematic illustration of a cross-sectional view of an integrated circuit device showing the processing step of forming a mask layer according to an embodiment of the invention;

FIG. 9 is a schematic illustration of a cross-sectional view of an integrated circuit device showing the processing step of forming the mask layer and solder resist layer opening according to an embodiment of the invention;

FIG. 10 is a schematic illustration of a cross-sectional view of an integrated circuit device showing the processing step of electroless plating according to an embodiment of the invention;

FIG. 11 is a schematic illustration of a cross-sectional view of an integrated circuit device showing the processing step electroplating layer according to an embodiment of the invention;

FIG. 12 is a schematic illustration of a cross-sectional view of an integrated circuit device showing the processing step of solder printing according to an embodiment of the invention;

FIG. 13 is a schematic illustration of a cross-sectional view of an integrated circuit device showing the processing step of solder reflow according to an embodiment of the invention; and

FIG. 14 is a schematic illustration of a cross-sectional view of an integrated circuit device showing the processing step of mask removal according to an embodiment of the invention.

### DETAILED DESCRIPTION OF EXEMPLARY EMBODIMENTS OF THE PRESENT INVENTION

Embodiments of the present invention may include apparatuses for performing the operations herein. An apparatus may be specially constructed for the desired purposes, or it may comprise a general purpose device selectively activated or reconfigured by a program stored in the device.

In an exemplary embodiment of the invention, a method of forming solder bumps is provided. A layer of metal may be formed over a bump pad on a package substrate. The layer of metal may include various discrete layers of metal, which may or may not be formed from the same material. A layer of solder may then be formed over the layer of metal. The solder layer may be formed directly on top of the metal layer. The solder layer may be formed by a solder printing process. The layer of metal may be thicker than the solder layer. The solder layer may then undergo reflow processing. The layer of metal may reduce the amount of solder used in forming a solder bump. By forming a solder bump as a combination of metal and solder, the number voids that may form in the solder bump can be greatly reduced or eliminated. Additionally, a method according to an exemplary embodiment of the invention may reduce the number of low/large solder volume defects and missing solder bump defects.

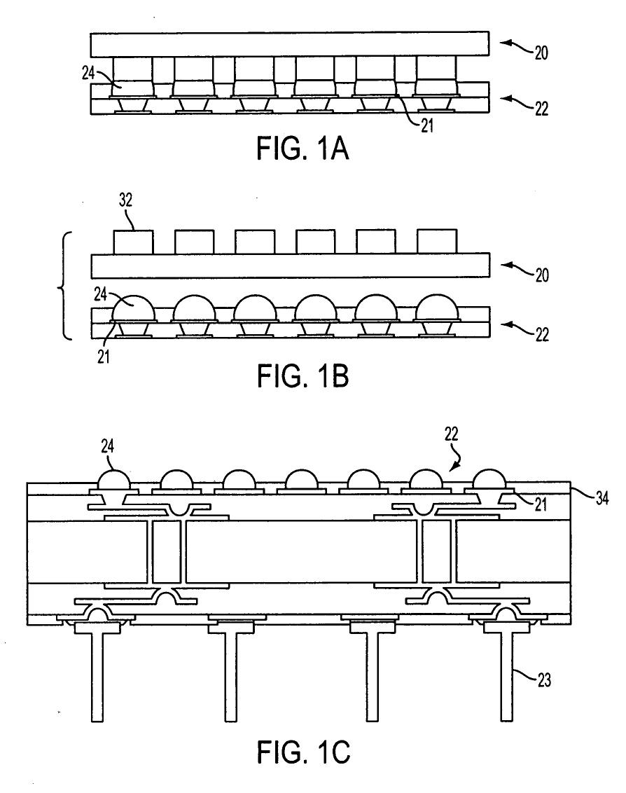

FIG. 1A is an illustration of a cross-section of integrated circuit device 20 after mounting to a package substrate 22. The device 20 may be mounted to the substrate 22 using technology known as Controlled Collapsible Chip Connection (C4), named after the package mounting technique of using solder to replace bond wires. The integrated circuit device 20 may be mounted to package substrate 22 by placing solder bumps on each of a number of bump pads to electrically couple each bump pad to its corresponding solder bump on the package substrate. Each corresponding solder bump on the package substrate is, in turn, coupled to an external pin. The integrated circuit device is mounted to the package substrate with its top-side facing towards the package substrate 22. In other words, the integrated circuit device is “flipped.” For this reason, the design of the integrated circuit device and its subsequent packaging method is also referred to as flip-chip technology.

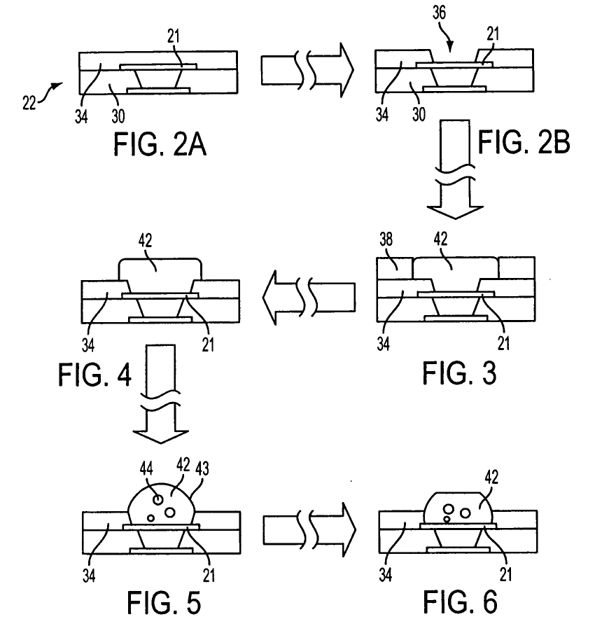

The solder bumps may be formed using known solder printing and solder reflow techniques. FIGS. 2-6 illustrate a prior method for forming solders bumps 24. Integrated circuit device 20 includes bump pads 32 (see FIGS. 1A-1C) that are available for electrical coupling to a corresponding pad 21 on packaged substrate 22. A layer of solder resist 34 is formed on the surface of the packaged substrate 22 and is patterned to expose only the bump pad surfaces 21 through via 36, FIGS. 2A and 2B. A stencil mask 38 may then be set on top of solder resist layer 34. Next, solder paste 42 may be deposited over the exposed bump pads 21 through a printing process as shown in FIG. 3. Next, as shown in FIG. 4, the stencil mask 38 may be removed to expose the solder 42. The packaged substrate 22 then may undergo a heat treatment reflow process. This process causes the solder 42 to soften and reflow such that the solder bump 42 has a generally smooth and curved outer surface 43 as is shown in FIG. 5. The outer surface 43 of the solder 42 may then be flattened so it may be more easily placed on the semiconductor integrated circuit device 20, FIG. 6. Voids 44 may form in the solder bumps 42 during formation and reflow.

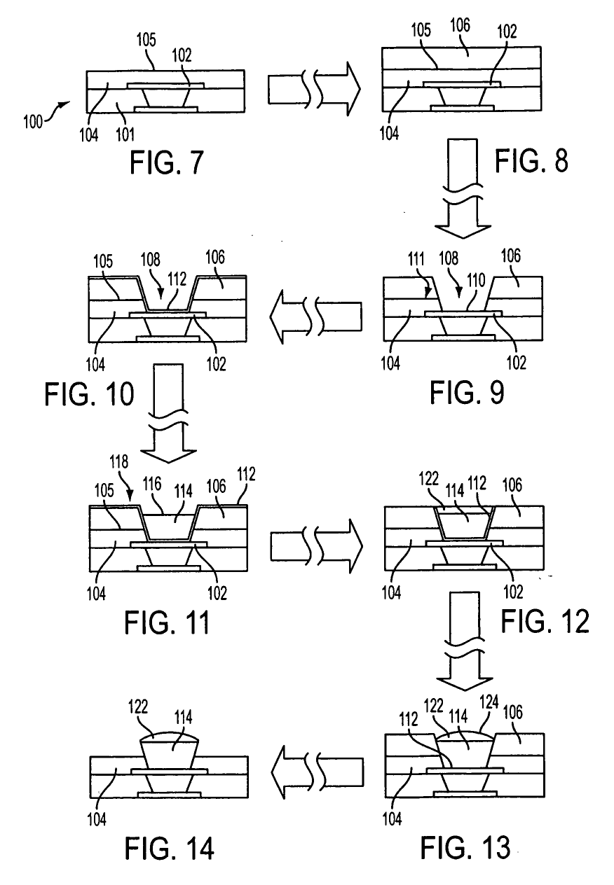

FIGS. 7-14 schematically illustrate cross-sectional side views of a portion of an integrated circuit device having a bump pad and demonstrate an exemplary embodiment of a method of forming a solder bump.

FIG. 7 shows a conventional integrated circuit device 100 having a bump pad 102 overlying a dielectric area 101 such as, for example, film and liquid epoxy resin.

A layer of solder resist 104 may be formed over the bump pad 102 as shown, for example, in FIG. 7. The solder resist 104 may be formed to a thickness of about 15-30 microns so that a top surface 105 of solder resist 104 is about 15-30 microns above substrate 101. The solder resist 104 may have heat resistant and chemical resistant properties that allow the solder resist 104 to withstand the subsequent heat and chemical processing that is described below. The solder resist 104 may be able to be patterned via ultraviolet photolithography processes, be stripped by an alkaline solution, and survive reflow processing at temperatures above 260 degrees C.

A mask resist 106, such as a photo or thermo-setting resin resist, may be formed over the solder resist 104 on the integrated circuit device 100 as shown in FIG. 8. The mask resist 106 may be formed to a depth of about 10-30 microns. Accordingly, the total thickness of the solder resist 104 and the mask resist 106 may be about 25-60 microns. The mask resist 106 may be able to be patterned via ultraviolet photolithography processes, be stripped by an alkaline solution, and survive reflow processing at temperatures above 260 degrees C.

As shown in FIG. 9, portions of the mask resist 106 and solder resist 104 may then be removed to expose the bump pad 102 through via 108. A top surface 110 of the bump pad 102, as well as sidewalls 111 of the solder resist 104 and mask resist 106, may be revealed by forming the via 108. The via 108 may be formed by patterning the solder resist 104 and mask resist 106 through lithography to expose an area over the bond pad 102 in order to remove the solder resist 104 and mask resist 106 in that area. Laser drilling may also be used to remove the solder resist 104 and mask resist 106 over the bond pad 102. Both of these techniques are well known to those of ordinary skill in the art.

Next, a metal layer may be formed in the via 108. The metal layer may be comprised of two or more separately formed metal layers. For example, the metal layer may include a first, thin metal layer followed be a second, thicker metal layer. The first metal layer may be applied to provide an electrical connection after the via 108 is formed. In the exemplary embodiment shown and described, a first metal layer 112 may be formed over the integrated circuit device 100, as shown in FIG. 10. The first metal layer 112 may be formed in the via 108, on sidewalls 111 of the solder resist 104 and on mask resist 106, as well as on the top surface 110 of the bond pad. The first metal layer 112 may be formed using electroless plating. The first metal layer 112 may be very thin, for example, it may have a thickness of about 0.1-0.9 microns. Copper or another conductive metal may be used to form the first metal layer 112.

As shown in FIG. 11, a second metal layer 114 may then be formed over the first metal layer 112. The second metal layer 114 may be electrically coupled to the first metal layer 112. Electroplating may be used to form the second metal layer 114. The second metal layer 114 may be formed in the via 108 to a level higher than the top surface 105 of the solder resist layer 104. However, the second metal layer 114 may not entirely fill the via 108. Some space may remain in the via 108 over the second metal layer 114 to receive a later applied layer of solder. Thus, a top surface 116 of the second metal layer 114 may be arranged adjacent to the mask layer 106. As shown in FIG. 11, the second metal layer 114 may be formed with a height reaching about a midpoint of the thickness of the mask layer 106. The total thickness of the first and second metal layers 112, 114 may be 30-50 microns. About 5-10 microns of space may be left between the top surface 116 of the second metal layer 114 and a top surface 118 of the mask layer 106. The metal layer may fill more than 75% of the space in the via. The second metal layer 114 may also be formed of the same material as the first metal layer 112, such as copper or another appropriate metal. The first and second metal layers 112, 114 may be confined to within the via 108, that is, on the sidewalls 111 of the solder resist 104 and mask resist 106 and the top surface 110 of the bond pad.

Next, as shown in FIG. 12, a solder layer 122 may be formed over the integrated circuit device 100. The solder layer 122 may be formed within the via 108 to be electrically connected to the metal layer. The solder layer 122 may be formed over the first and second metal layers 112, 114 that overlie the bump pad 102. The solder layer 122 may be about 5-10 microns thick. The solder layer 122 may be formed in the space in the via 108 above the second metal layer 114. The solder layer 122 may be, for example, a solder bump that is deposited by way of an electroplating process using, for example, a single cup plater. Alternatively, the solder layer 122 may be formed by solder printing. Both of these techniques are well known to those of ordinary skill in the art.

At this point, the solder layer 122 may be subjected to a reflow process. This may be accomplished, for example, via a heat treatment reflow process. An oven may be heated, for example, to up to 260 degrees C. in a hydrogen atmosphere, the integrated circuit device placed therein, and then cooled. In one embodiment, the reflow process may take approximately one-three minutes to ramp the oven up to the appropriate temperature. It is to be appreciated that the reflow process conditions may vary for a particular process. The reflow process may melt the solder and allow it to cool and reform in the form of a spherical shape with a top surface 124 that may be smooth, as shown in FIG. 13. The solder may then be allowed to cool.

The mask layer 106 may then be removed to expose the underlying solder resist 104 as shown in FIG. 14. The mask layer 106 may be stripped by an alkaline solution or other appropriate method. A layer of solder may be formed on top of the metal layer. The solder may then be used to create a conductive connection to appropriately wire the integrated circuit device.

In the above description, the use of solder bumps in a C4 platform packaging technology is described. It is to be appreciated, however, that the invention is not limited to the C4 platform. Instead, the process described above may be used and is contemplated for use in any process where conductive bumps may be used in assembly technology.

The embodiments illustrated and discussed in this specification are intended only to teach those skilled in the art ways known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

What is claimed is:

1. A method, comprising:
forming a via in a substrate to expose a pad;
forming a layer of conductive metal in the via on the pad; and
forming a solder layer in the via over the metal layer.

2. The method of claim 1, wherein the substrate comprises a solder resist layer.

3. The method of claim 2, further comprising forming a mask layer over the solder resist layer.

4. The method of claim 3, further comprising performing photolithography to form the via through the solder resist and the mask layer.

5. The method of claim 3, further comprising performing laser drilling to form the via through the solder resist and the mask layer.

6. The method of claim 1, wherein forming a layer further comprises performing electroless plating to form a first metal layer in the via.

7. The method of claim 6, further comprising performing electroplating to form a second metal layer thicker than the first metal layer over the first metal layer.

8. The method of claim 7, wherein the first and second layer are together about 30-50 microns thick.

9. The method of claim 7, wherein forming a solder layer comprises forming the solder layer in the via over the second metal layer.

10. The method of claim 1, wherein forming the solder layer further comprises printing the solder layer.

11. The method of claim 1, wherein forming the solder layer further comprises plating the solder layer.

12. The method of claim 1, wherein forming the solder layer further comprises reflowing the solder layer.

13. The method of claim 1, further comprising placing the solder layer in heat of about 260 degrees C.

14. A method, comprising:
forming a solder resist layer on a substrate;
forming a mask layer on the solder resist;
forming a via through the solder resist and the mask layer to expose a pad;
partially filling the via with a conductive metal;
forming a solder layer in the via in conductive contact with the metal; and
performing solder reflow.

15. The method of claim 14, further comprising filling the via with the metal to a level higher than the solder resist layer.

16. The method of claim 14, further comprising:
performing electroless plating to form a first metal layer on a bottom and sidewalls of the via; and
performing electroplating to form a second metal layer in via on top of the first metal layer.

17. An integrated circuit device, comprising:
a substrate;
a bump pad formed on the substrate;
an insulating layer formed on the substrate over the bump pad;
a via in the insulating layer exposing at least a portion of a top surface of the bump pad, the via including sidewalls;
a first metal layer formed in the via on the top surface of the bump pad;
a second metal layer formed on the first metal layer in the via to a level higher than the insulating layer; and
a solder layer conductively coupled to the second metal layer.

18. The integrated circuit device of claim 17, wherein the first metal layer is about 0.1-0.9 microns thick.

19. The integrated circuit device of claim 17, wherein the second metal layer is about 30-50 microns thick.

20. The integrated circuit device of claim 17, wherein the insulating layer is about 15-30 microns thick.

21. The integrated circuit device of claim 17, wherein the first and second metal layers are comprised of copper.
